(19) United States
(12) Patent Application Publication
(10) Pub. No.: US 2016/0113110 A1
(43) Pub. Date: Apr. 21, 2016

(54) PRINTED WIRING BOARD

(71) Applicant: IBIDEN CO., LTD., Ogaki-shi (JP)

(72) Inventors: Takeshi FURUSAWA, Ogaki-shi (JP); Kota NODA, Ogaki-shi (JP)

(73) Assignee: IBIDEN CO., LTD., Ogaki-shi (JP)

(21) Appl. No.: 14/918,784

(22) Filed: Oct. 21, 2015

(30) Foreign Application Priority Data
Oct. 21, 2014 (JP) 2014-214547

(51) Int. Cl. H05K 1/02; H05K 1/11

(52) U.S. Cl. CPC H05K 1/0298; H05K 1/115; H05K 2201/09827; H05K 2201/068; H05K 2201/096

(57) ABSTRACT

A printed wiring board includes a substrate, a first conductor layer formed on first surface of the substrate, a second conductor layer formed on second surface of the substrate, a through-hole conductor penetrating through the substrate and connecting the first and second conductor layers, a build-up layer formed on the second surface of the substrate and including conductor layers and insulating layers, and a first insulating layer formed on the first surface of the substrate such that the first insulating layer is covering the first conductor layer on the substrate. The substrate has a cavity penetrating through the first insulating layer and substrate such that the cavity is exposing the build-up layer on the second surface of the substrate, and the substrate and insulating layers in the build-up layer are formed such that difference between thermal expansion coefficients of the substrate and insulating layers is set 15 ppm or less.

### CROSS-REFERENCE TO RELATED APPLICATIONS

The present application is based upon and claims the benefit of priority to Japanese Patent Application No. 2014-214547, filed Oct. 21, 2014, the entire contents of which are incorporated herein by reference.

### BACKGROUND OF THE INVENTION

1. Field of the Invention

The present invention relates to a printed wiring board having a cavity for exposing a mounting area.

2. Description of Background Art

Japanese Patent Laid-Open Publication No. 2007-123524 describes a substrate with a built-in electronic component, which includes a coreless substrate and a resin layer. An accommodating part (for accommodating a semiconductor chip) and a through via are formed in the resin layer. The entire contents of this publication are incorporated herein by reference.

### SUMMARY OF THE INVENTION

According to one aspect of the present invention, a printed wiring board includes a substrate, a first conductor layer formed on a first surface of the substrate, a second conductor layer formed on a second surface of the substrate, a through-hole conductor penetrating through the substrate such that the through-hole conductor is connecting the first conductor layer and the second conductor layer, a build-up layer formed on the second surface of the substrate and including conductor layers and insulating layers, and a first insulating layer formed on the first surface of the substrate such that the first insulating layer is covering the first conductor layer on the first surface of the substrate. The substrate has a cavity penetrating through the first insulating layer and the substrate such that the cavity is exposing the build-up layer laminated on the second surface of the substrate, and the substrate and the insulating layers in the build-up layer are formed such that a difference between a thermal expansion coefficient of the substrate and a thermal expansion coefficient of the insulating layers in the build-up layer is set in a range of 15 ppm or less.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view of a printed wiring board according to an embodiment of the present invention;

FIG. 1B is a plan view illustrating a first circuit substrate and a mounting area that is exposed from an opening of the first circuit substrate;

FIGS. 2A and 2B are cross-sectional views of application examples of the printed wiring board according to the embodiment;

FIG. 3A-3E are process diagrams illustrating a method for manufacturing the printed wiring board of the embodiment;

FIG. 4A-4C are process diagrams illustrating the method for manufacturing the printed wiring board of the embodiment;

FIG. 5A-5D are process diagrams illustrating the method for manufacturing the printed wiring board of the embodiment;

FIG. 6A illustrates a cross-sectional view of a printed wiring board of a first modified example of the embodiment;

FIG. 6B illustrates a schematic diagram of a through hole;

FIG. 6C illustrates a contact point. FIG. 6D illustrates a recess;

FIG. 7A is a plan view of an intermediate substrate;

FIG. 7B illustrates a dummy pattern;

FIGS. 7C and 7D illustrate a method for forming an opening; and

FIG. 7E illustrates a cross-section of a printed wiring board of a second modified example of the embodiment.

### DETAILED DESCRIPTION OF THE EMBODIMENTS

The embodiments will now be described with reference to the accompanying drawings, wherein like reference numerals designate corresponding or identical elements throughout the various drawings.

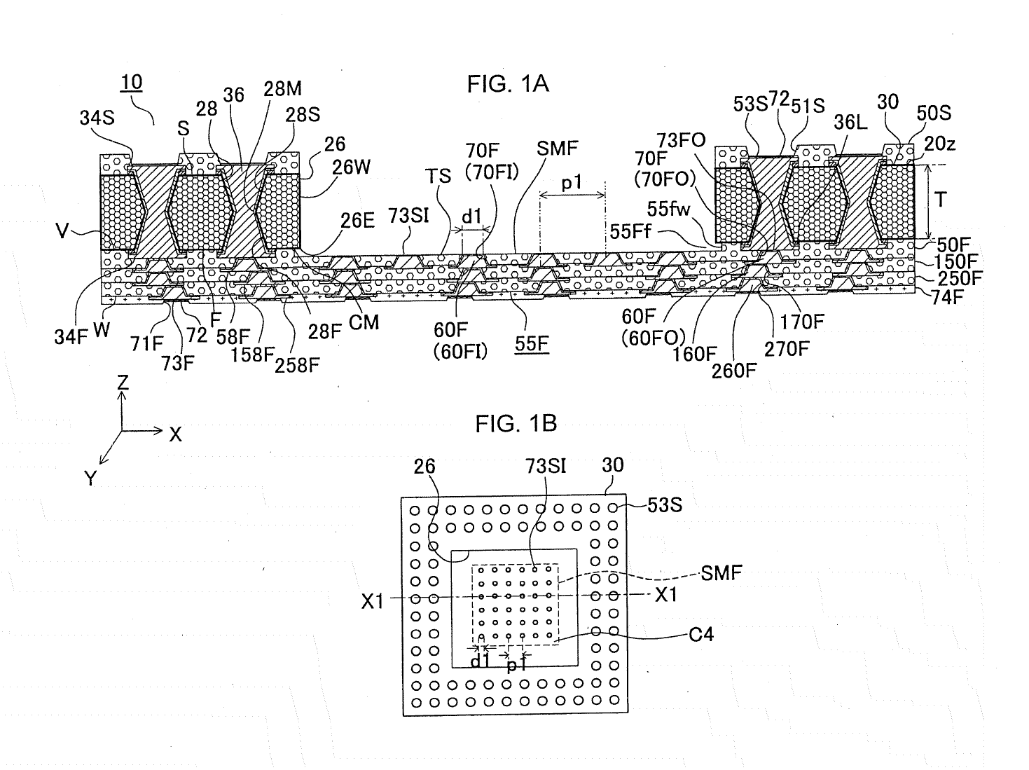

FIG. 1A illustrates a printed wiring board 10 of an embodiment. The printed wiring board 10 of the present embodiment includes a first circuit substrate 30 that has a first surface (S) and a second surface (F) that is on an opposite side of the first surface, and a second circuit substrate (55F) that has a third surface (V) and a fourth surface (W) that is on an opposite side of the third surface.

The second circuit substrate (55F) illustrated in FIG. 1A is formed as a build-up layer that is formed by conductor layers (58F, 158F, 258F) and resin insulating layers (50F, 150F, 250F) that are alternately laminated. The second circuit substrate (55F) is laminated on the second surface (F) of the first circuit substrate 30. The third surface (V) of the second circuit substrate and the second surface (F) of the first circuit substrate are in contact with each other.

The resin insulating layers of the second circuit substrate are formed of resin and inorganic particles. Further, the resin insulating layers (50F, 150F, 250F) may each contain a reinforcing member such as a glass cloth. By allowing the resin insulating layers (50F, 150F, 250F) to each contain a reinforcing member, occurrence of a crack in the second circuit substrate is suppressed.

The resin insulating layers each have openings for via conductors, and the openings each taper from the fourth surface (W) side toward the third surface (V) side.

Via conductors (60F, 160F, 260F) are formed in the openings of the resin insulating layers. The via conductors each have a side wall that tapers from the fourth surface (W) side toward the third surface (V) side. Conductor layers that are adjacent to each other are connected by the via conductors.

The second circuit substrate (55F) has a mounting area (SMF) illustrated in FIG. 1B at a substantially central portion of the third surface (V). An X1-X1 cross section in FIG. 1B corresponds to FIG. 1A. The mounting area is exposed by an opening 26 of the first circuit substrate. An electronic component such as an IC chip is mounted in the mounting area.

The first circuit substrate illustrated in FIG. 1A is formed by an insulating substrate (20z) that contains resin and a reinforcing member, a first conductor layer (34S), a second conductor layer (34F), and through-hole conductors 36. The insulating substrate has a first surface (S) and a second surface (F) that is on an opposite side of the first surface (S). The first surface of the insulating substrate and the first surface of the first circuit substrate are the same surface. The second surface of the insulating substrate and the second surface of the first circuit substrate are the same surface. The insulating substrate may further contain inorganic particles. The first conductor layer (34S) is formed on the first surface, and the second conductor layer (34F) is formed on the second surface. The first conductor layer and the second conductor layer are connected by the through-hole conductors. The first circuit substrate further has the opening 26 for exposing the mounting area (SMF) of the second circuit substrate. In FIG. 1A, the printed wiring board does not have a conductor layer on the first conductor layer. In this case, the first conductor layer is an uppermost conductor layer.

As illustrated in FIG. 1A, the first resin insulating layer (50F) is formed on the second surface (F) and the second conductor layer (34F) of the first circuit substrate 30. Openings (70F) (70FI, 70FO) for via conductors (60F) (60FI, 60FO) that penetrate the resin insulating layer (50F) are formed in the first resin insulating layer (50F).

The conductor layer (58F) in the second circuit substrate is formed on the first resin insulating layer (50F).

The via conductors (60F) are formed in the openings (70F) for the via conductors (60F). The via conductors (60F) include connection via conductors (60FO) that connect the conductor layer (conductor layer in the second circuit substrate) (58F) and the second conductor layer (34F) and mounting via conductors (60FI) for mounting an electronic component. It is preferable that the connection via conductors (60FO) be directly connected to lands (36L) of the through-hole conductors in the first circuit substrate. A land (36L) is formed by a conductor covering a through-hole conductor and a conductor that surrounds the through-hole conductor, and is contained in the second conductor layer (34F).

The mounting via conductors are formed in the mounting area (SMF). The mounting via conductors (60FI) are formed in the openings (70FI) for the via conductors of the first resin insulating layer (50F). Bottoms (C4 pads) (73SI) of the mounting via conductors (60FI) are exposed by the openings (70FI). Further, the bottoms (73SI) are exposed by the opening 26 of the first circuit substrate. The bottoms (C4 pads) of the mounting via conductors are exposed by the opening 26 and the openings (70FI).

The connection via conductors (60FO) are respectively formed in the openings (70FO) of the first resin insulating layer (50F). Bottoms (73FO) of the connection via conductors (60FO) are respectively directly connected to the lands (36L) of the through-hole conductors.

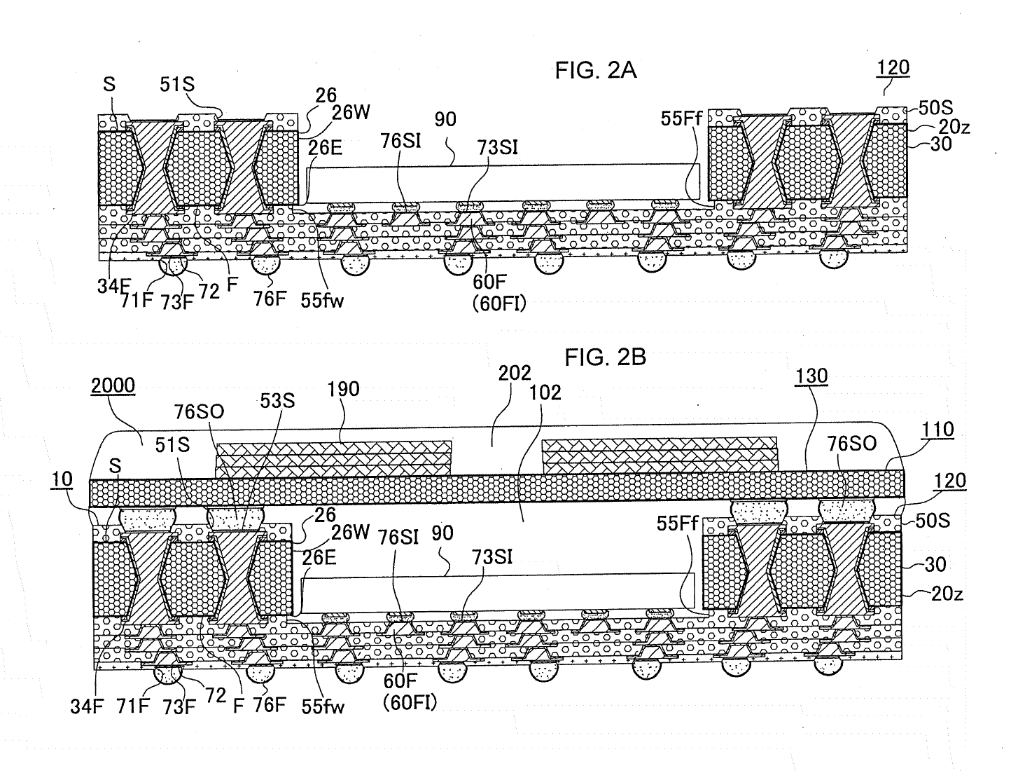

As illustrated in FIG. 1A, the bottoms of the mounting via conductors (60FI) that penetrate the resin insulating layer (first resin insulating layer) (50F) are exposed and function as first pads (C4 pads) (73SI). The first pads are formed in the mounting area of the second circuit substrate. Solder bumps (76SI) (see FIG. 2A) for connecting to an electronic component can be formed on the first pads (73SI).

In the present embodiment, the pads (first pads) (73SI) for mounting an electronic component 90 are the bottoms of the mounting via conductors (60FI). The first pads of the printed wiring board of the present embodiment do not have lands for mounting an electronic component. According to the present embodiment, the pads for mounting an electronic component can have a small size (diameter (dl)). Therefore, the pads can have a narrow pitch (p1). According to the present embodiment, the printed wiring board can be reduced in size. Warpage of the printed wiring board is reduced. Connection reliability between the printed wiring board and an electronic component is improved. A printed wiring board that allows an electronic component to be easily mounted is provided.

In the printed wiring board of the present embodiment, the openings for the via conductors taper from a lower surface of the resin insulating layer toward an upper surface of the resin insulating layer. Therefore, the size of the pads can be further reduced. The pitch of the first pads can be further reduced. The size of the printed wiring board can be reduced. A sophisticated electronic component can be mounted on the printed wiring board.

As illustrated in FIG. 1A, the second resin insulating layer (150F) is formed on the first resin insulating layer (50F) and the conductor layer (58F). Openings (170F) for the second via conductors (160F) that penetrate the second resin insulating layer (150F) are formed in the resin insulating layer (150F).

The second conductor layer (158F) in the second circuit substrate is formed on the second resin insulating layer (150F).

The second via conductors (160F) are formed in the openings (170F) for the second via conductors (160F). The second via conductors (160F) connect the conductor layer (158F) (the second conductor layer in the second circuit substrate) and the conductor layer (58F).

The third resin insulating layer (250F) is formed on the second resin insulating layer (150F) and the second conductor layer (158F). Openings (270F) for the third via conductors (260F) that penetrate the third resin insulating layer (250F) are formed in the resin insulating layer (250F).

The third conductor layer (258F) in the second circuit substrate is formed on the third resin insulating layer (250F).

The third via conductors (260F) are formed in the openings (270F) for the third via conductors. The third via conductors (260F) connect the conductor layer (258F) (the third conductor layer in the second circuit substrate) and the conductor layer (158F). The third conductor layer (258F) is a lowermost conductor layer of the printed wiring board 10.

The printed wiring board can have a resin insulating layer (74F) on a build-up layer on the resin insulating layer (lowermost resin insulating layer) (250F) and the conductor layer (lowermost conductor layer) (258F) of the second circuit substrate. Openings (71F) that expose the conductor layer (lowermost conductor layer) (258F) are formed in the resin insulating layer (74F) on the build-up layer. Portions of the conductor layer (258F) that are exposed by the openings (71F) function as pads (73F) that connect to a motherboard. It is desirable that a material same as that for the resin insulating layers (50F, 150F, 250F) used in the second circuit substrate be used for the resin insulating layer (74F) formed on the lowermost resin insulating layer (250F). The resin insulating layer (74F) on the build-up layer may be a solder resist layer.

A protective film 72 can be formed on each of the pads (73F). The protective film is a film for preventing oxidation of the pad. The protective film is formed, for example, by a Ni/Au, Ni/Pd/Au, Pd/Au or OSP (Organic Solderability Preservative) film.

A protective film can be formed on each of the bottoms (C4 pads) of the mounting via conductors (60FI).

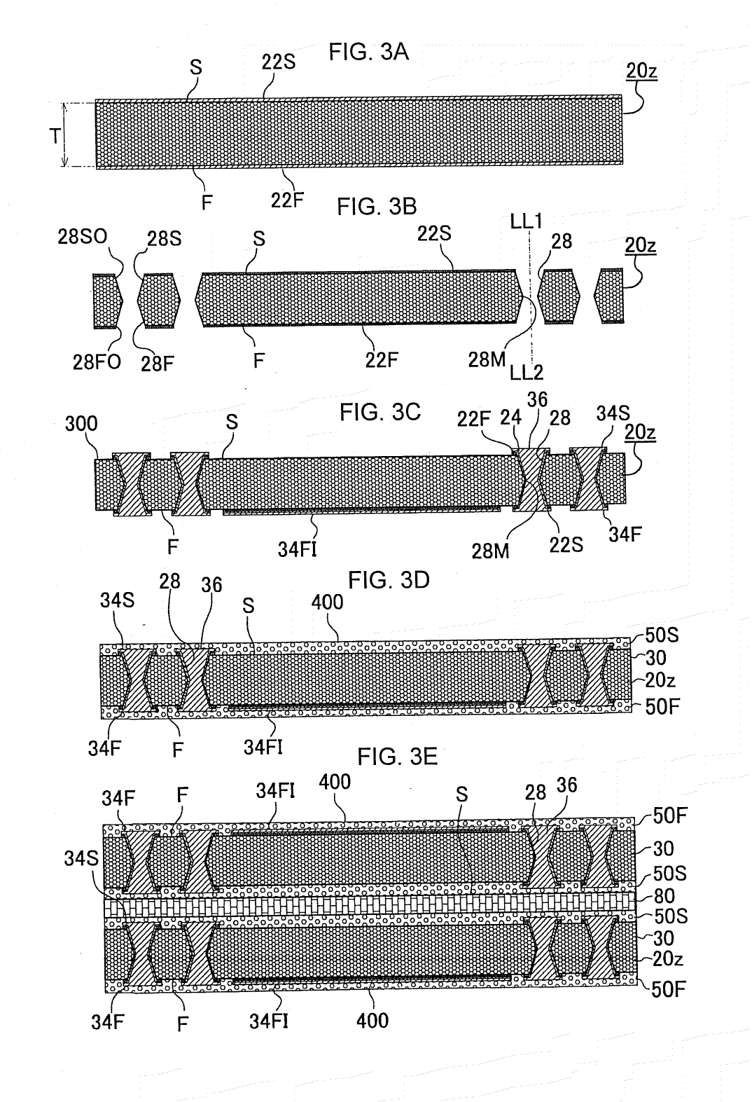

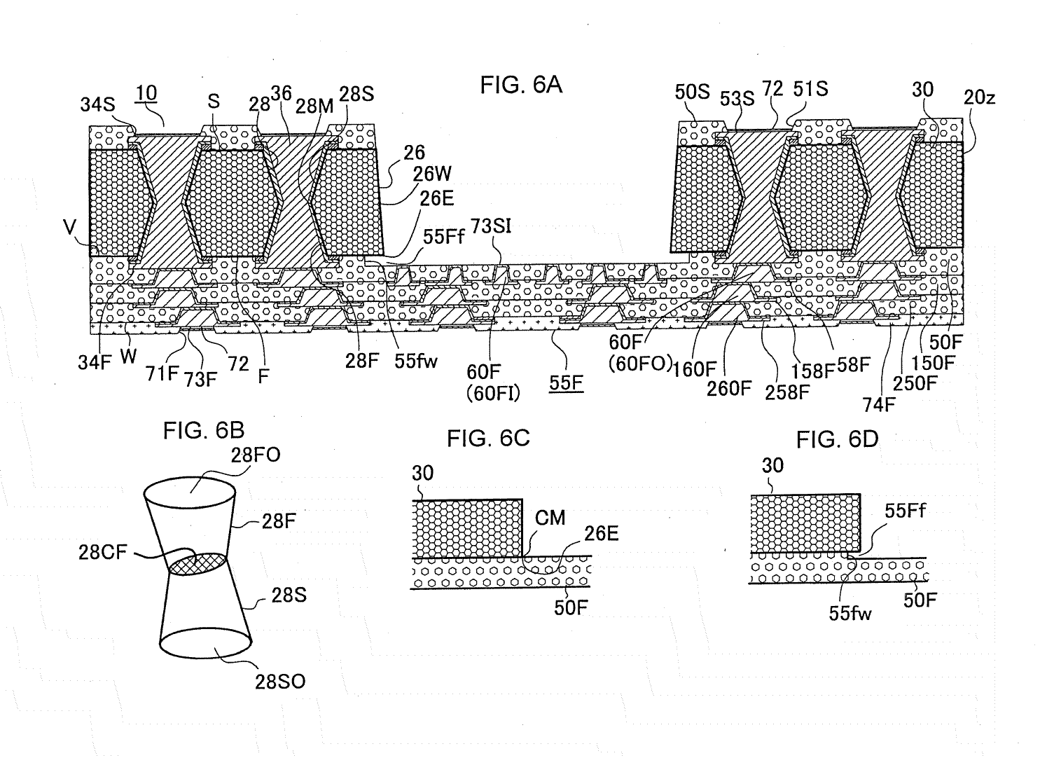

As illustrated in FIG. 3B, through holes 28 are formed that each include a first opening part (28S) and a second opening part (28F), the first opening part (28S) having a first opening (28SO) on the first surface (S) of the insulating substrate (20z), and the second opening part (28F) having a second opening (28FO) on the second surface (F) of the insulating substrate (20z). The through holes 28 each have a joining interface. The first opening part and the second opening part are connected by the joining interface (28CF). The joining interface (28CF) is illustrated in FIG. 6B. Oblique lines are drawn in the joining interface (28CF). A place where a side wall of the first opening part and a side wall of the second opening part intersect is a connecting part (28M). It is preferable that the joining interface have a size smaller than that of the first opening. It is preferable that the joining interface have a size smaller than that of the second opening. It is preferable that the first opening part (28S) taper from the first surface toward the second surface. It is preferable that the second opening part (28F) taper from the second surface toward the first surface. The through-hole conductors 36 are formed in the through holes 28 that each have such a shape. The through-hole conductors 36 illustrated in FIG. 1A may be manufactured, for example, using a method described in U.S. Pat. No. 7,786,390. The entire contents of this patent are incorporated herein by reference.

As illustrated in FIG. 1A or FIG. 6A, the opening 26 exposes the mounting area (SMF) of the second circuit substrate. The bottoms of the via conductors (mounting via conductors) (60FI) that penetrate the first resin insulating layer (50F) that is in contact with the first circuit substrate are exposed by the opening 26.

The insulating substrate (20z) is formed of a reinforcing member and resin. The insulating substrate (20z) may further contain inorganic particles. Examples of the reinforcing member include a glass fiber, a glass cloth and an aramid fiber. Examples of the inorganic particles include silica and alumina particles.

The printed wiring board can have a resin insulating layer (50S) on the first surface (S) and the first conductor layer (34S) of the first circuit substrate 30. Openings (51S) that expose the first conductor layer (34S) are formed in the upper side resin insulating layer (50S). Portions of the first conductor layer (34S) that are exposed by the openings (51S) function as pads (second pads) (53S) for mounting a second package substrate 130. A protective film 72 can be formed on each of the second pads. The second package substrate 130 is illustrated in FIG. 2B. It is desirable that a material same as that for the resin insulating layers (50F, 150F, 250F) used in the second circuit substrate be used for the resin insulating layer (50S) formed on the first conductor layer (34S). However, the upper side resin insulating layer (50S) may be a solder resist layer.

The through holes formed in the first circuit substrate of the present embodiment each have the connecting part (28M). The connecting part is a changing point, and thus, the connecting part (28M) is susceptible to a stress. Therefore, in the present embodiment, it is likely that a stress is distributed to contact points (CM) and connecting parts (28M). Thus, a crack hardly occurs from a contact point (CM) to the second circuit substrate. Further, metal is formed at the joining interface (28CF) by a plating film. Metal is more stress resistant than resin. Therefore, even when stress is concentrated on the joining interface (28CF), a crack hardly occurs from the connecting part (28M) or the joining interface (28CF) to the through-hole conductor. The insulating substrate (20z) has a reinforcing member. Therefore, a crack hardly occurs in the first circuit substrate.

When a substrate with a built-in electronic component does not have a connecting part (28M), it is likely that stress concentrates only on a contact point between a corner of the resin layer and a coreless substrate. A crack is likely to enter from the contact point to the coreless substrate.

FIG. 2A illustrates a first application example 120 of the printed wiring board 10 of the present embodiment. The first application example 120 is a package substrate (first package substrate).

In the package substrate 120, the electronic component 90 such as an IC chip is accommodated in the opening 26 of the first circuit substrate 30. The IC chip 90 is mounted by the solder bumps (76SI) on the C4 pads (73SI) that are exposed from the opening 26.

FIG. 2B illustrates a second application example (POP substrate) 2000 of the printed wiring board 10 of the present embodiment. In the second application example, the second package substrate 130 is mounted on the first package substrate 120 via connecting bodies (76SO). The second package substrate 130 includes an upper substrate 110 and an electronic component 190 such as a memory mounted on the upper substrate. The connecting bodies (76SO) are formed on the portions (second pads) (53S) of the second conductor layer that are exposed by the openings (51S) of the upper side resin insulating layer (50S). In FIG. 2B, the connecting bodies (76SO) are solder bumps (76SO). Examples of the connecting bodies other than the solder bumps include metal posts such as plating posts or pins (not illustrated in the drawings). The plating posts or pins each have a shape of a circular cylinder. A right circular cylinder is preferable.

A mold resin 102 is formed between the first package substrate 120 and the second package substrate 130. A mold resin 202 that seals the electronic component 190 is formed on the upper substrate 110.

The first circuit substrate can have resin insulating layers and conductor layers that are alternately laminated on the first surface of the insulating substrate (20z) and on the first conductor layer. In this case, the upper side resin insulating layer (50S) is formed on the resin insulating layers and the conductor layers. In this case, a conductor layer immediately below the upper side resin insulating layer (50S) is an uppermost conductor layer.

The printed wiring board 10 may have solder bumps (76F) for connecting to a motherboard on the pads (73F) that are exposed from the openings (71F) of the resin insulating layer (74F) on the build-up layer.

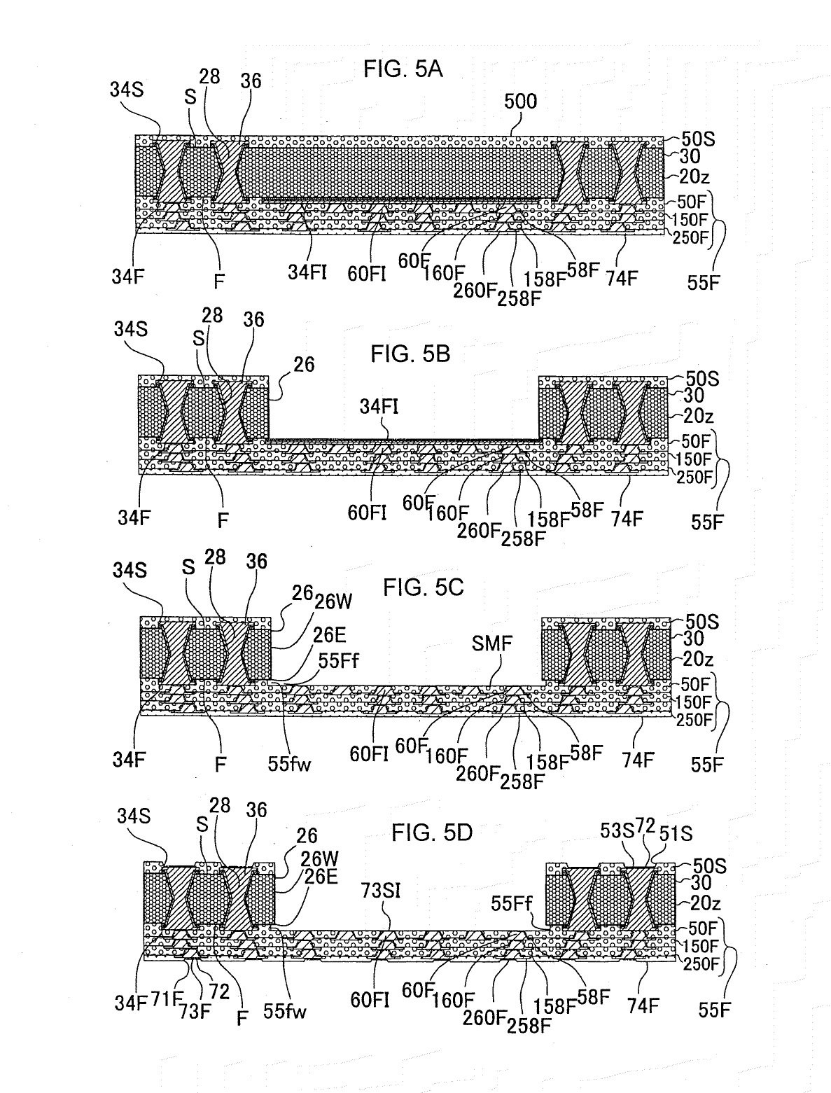

In the printed wiring board of the present embodiment, the opening 26 for accommodating an electronic component is formed in the insulating substrate (20z). Suppose the second circuit substrate is formed on both sides of the first circuit substrate, in this case, a structure symmetrical about the first circuit substrate is obtained. Therefore, stress acting on a contact point (CM) is small. However, in the printed wiring board of the present embodiment, the second circuit substrate is formed only on the second surface of the first circuit substrate. Therefore, in order to avoid stress concentration, a recess (55Ff) can be formed in the printed wiring board of the present embodiment. The printed wiring board having the recess (55Ff) is illustrated in FIGS. 6D and 5D. The recess (55Ff) is a space formed between the first circuit substrate 30 and the second circuit substrate (55F) and is connected to the opening 26. An upper surface of the recess is the second surface of the first circuit substrate. A lower surface of the recess is the third surface of the second circuit substrate. A side wall (55fw) of the recess is a side surface of the first resin insulating layer (50F) that is in contact with the first circuit substrate. The side wall (55fw) of the recess (55Ff) is recessed from a side wall (26W) of the insulating substrate (20z) that is exposed by the opening 26. Due to the recess (55Ff), a corner part (26E) of the first circuit substrate 30 having a high rigidity is not in contact with the second circuit substrate. Even when a stress due to thermal contraction concentrates on the corner part (26E), the stress does not reach from the corner part to the second circuit substrate. A crack is unlikely to occur in the second circuit substrate. The reliability of the printed wiring board having the recess (55Ff) does not decrease. In the printed wiring board of the first embodiment, the third surface (V) of the second circuit substrate that is exposed from the opening 26 is recessed from the second surface of the first circuit substrate. In this case, a surface (TS) that is exposed from the opening 26 is positioned below the second surface of the first circuit substrate. The lower surface of the recess (55Ff) (the upper surface of the first resin insulating layer (50F) in the recess) connects to the surface (TS) exposed from the opening 26. The lower surface of the recess and the surface (TS) are positioned on the same plane. In the printed wiring board having the recess (55Ff), the upper surface of the first resin insulating layer (50F) is formed by the surface (V) that is in contact with the first circuit substrate, the surface (TS) that is exposed from the opening 26, and the side wall (55fw) that connects the surface (V) and the surface (TS). The surface (V) and the surface (TS) are not positioned on the same plane and thus the side wall (55fw) exists. The side wall (55fw) is a surface that is exposed from the recess (55Ff).

In the printed wiring board of the present embodiment, the resin insulating layer (50S) as an outermost layer on the first surface (S) side of the first circuit substrate 30 is a resin layer that does not contain a core material. Further, the resin insulating layers (50F, 150F, 250F) that form the build-up layer (55F) on the second surface (F) side of the first circuit substrate 30 are also resin layers that do not contain a core material. It is desirable that the same material be used for the resin insulating layer (50S) as the outermost layer on the first surface (S) side of the first circuit substrate 30 and for the resin insulating layers (50F, 150F, 250F) that form the build-up layer (55F) on the second surface (F) side of the first circuit substrate 30.

The insulating substrate (20z) that forms the first circuit substrate 30 is formed by laminating a prepreg that is obtained by impregnating a core material with resin. Examples of the core member include a glass cloth, a glass fiber and an aramid fiber. Examples of the resin include an epoxy resin and a BT (bismaleimide triazine) resin. The insulating substrate (20z) has a thermal expansion coefficient of 10-25 ppm and a thickness (T) of 50 μm-200 μm. The resin insulating layers (50F, 150F, 250F) that form the build-up layer (55F) are formed of a resin that does contain a core material but contains inorganic filler. Examples of the resin include an epoxy resin and a resin containing primarily a BT (bismaleimide triazine) resin. Examples of the inorganic filler include particles of one or more compound selected from an aluminum compound, a calcium compound, a potassium compound, a magnesium compound and a silicon compound. The examples of the inorganic filler further include particles of silica, alumina, dolomite and the like. By containing 40-80 wt % of the inorganic filler, the resin insulating layers (50F, 150F, 250F) are adjusted to have a thermal expansion coefficient of 25-40 ppm. That is, a difference between the thermal expansion coefficient of the first circuit substrate and the thermal expansion coefficient of the resin insulating layers (50F, 150F, 250F) is adjusted to 15 ppm or less. A material of the same composition as the resin insulating layers of the build-up layer can be used for the resin insulating layer (50S) on the first surface (S) side of the first circuit substrate.

A printed wiring board according to the first embodiment of the present invention has an asymmetric structure in which the one resin insulating layer (50S) is formed on the first surface (S) side of the first circuit substrate 30 and the three resin insulating layers (50F, 150F, 250F) are formed on the second surface (F) side of the first circuit substrate 30. Further, the cavity (openings) 26 is formed in the first circuit substrate 30 and thus rigidity of the first circuit substrate is reduced. Therefore, when a thermal stress is applied to the first circuit substrate 30 and the resin insulating layers (50F, 150F, 250F) of the build-up layer, warpage is likely to occur in the printed wiring board. Therefore, the difference between the thermal expansion coefficient of the first circuit substrate and the thermal expansion coefficient of the resin insulating layers of the build-up layer is set to 15 ppm or less, the thermal expansion coefficient of the first circuit substrate and the thermal expansion coefficient of the resin insulating layers of the build-up layer are similar to each other. Thereby, occurrence of warpage is suppressed. As a result, mounting reliability of the electronic component 90 is improved. Further, since warpage due to heat cycles is suppressed, a decrease in connection reliability between the electronic component 90, the upper substrate 110 and the printed wiring board 10 is reduced.

The resin insulating layer (74F) on the build-up layer (55F) is provided on the outermost resin insulating layer (250F) of the build-up layer. Thereby, a CET (thermal expansion coefficient) difference between the first surface side and the second surface side can be reduced, and warpage can be suppressed.

### Method for Manufacturing Printed Wiring Board

A method for manufacturing the printed wiring board 10 of the present embodiment is illustrated in FIG. 3A-5D.

A starting substrate is prepared. The starting substrate is formed by the insulating substrate (20z) and copper foils (22S, 22F) that are respectively laminated on both sides of the insulating substrate (20z) (FIG. 3A). The insulating substrate (20z) has a thermal expansion coefficient of 10-25 ppm and a thickness (T) of 50 μm-200 μm. The insulating substrate includes a reinforcing member, resin and inorganic particles. Examples of the reinforcing member include a glass cloth, a glass fiber and an aramid fiber. Examples of the resin include an epoxy resin and a BT (bismaleimide triazine) resin.

The insulating substrate has the first surface (S) and the second surface (F) that is on an opposite side of the first surface (S). The copper foil (22S) that is laminated on the first surface (S) of the insulating substrate is a first copper foil; and the copper foil (22F) that is laminated on the second surface (F) of the insulating substrate is a second copper foil.

CO2 laser is irradiated to the first copper foil (22S) of the starting substrate. The first opening part (28S) is formed on the first surface (S) side of the insulating substrate (20z). Further, CO2 laser is irradiated to the second copper foil (22F). The second opening part (28F) that connects to the first opening part (28S) is formed on the second surface (F) side. The first opening part (28S) and the second opening part (28F) are connected by the joining interface (28CF). The joining interface (28CF) is illustrated in FIG. 6B. The connecting part (28M) is formed at an intersection point of the side wall of the first opening part and the side wall of the second opening part. Laser is irradiated such that an axis (LL1) of the first opening part and an axis (LL2) of the second opening part coincide. The through holes 28 for the through-hole conductors are formed (FIG. 3B). The first opening part tapers from the first surface (S) toward the second surface (F). The second opening part tapers from the second surface (F) toward the first surface (S). The first opening part has the first opening (28SO) on the first surface; and the second opening part has the second opening (28FO) on the second surface.

An electroless plating film is formed on the first copper foil, the second copper foil, and side walls of the through holes 28. A plating resist film is formed on the electroless plating film. Thereafter, the through-hole conductors 36 in the through holes 28 and a pattern are formed by electrolytic plating. The plating resist film is peeled off. The electroless plating film and the copper foils (22F, 22S) below the plating resist film are removed using an etching solution. As a result, the first conductor layer (34S) is formed on the first surface of the insulating substrate. The second conductor layer (34F) is formed on the second surface of the insulating substrate. The second conductor layer (34F) includes a dummy pattern (34F1) for forming the opening 26. The through-hole conductors 36 that connect the first conductor layer and the second conductor layer are formed in the through holes 28. Each of the through-hole conductors has a thinnest portion at the connecting part (28M) of the through hole. An intermediate substrate 300 is obtained that includes the insulating substrate that has the through holes 28, the through-hole conductors 36 that are formed in the through holes 28, the first conductor layer (34S) that is formed on the first surface of the insulating substrate, and the second conductor layer (34F) that is formed on the second surface insulating substrate (FIG. 3C).

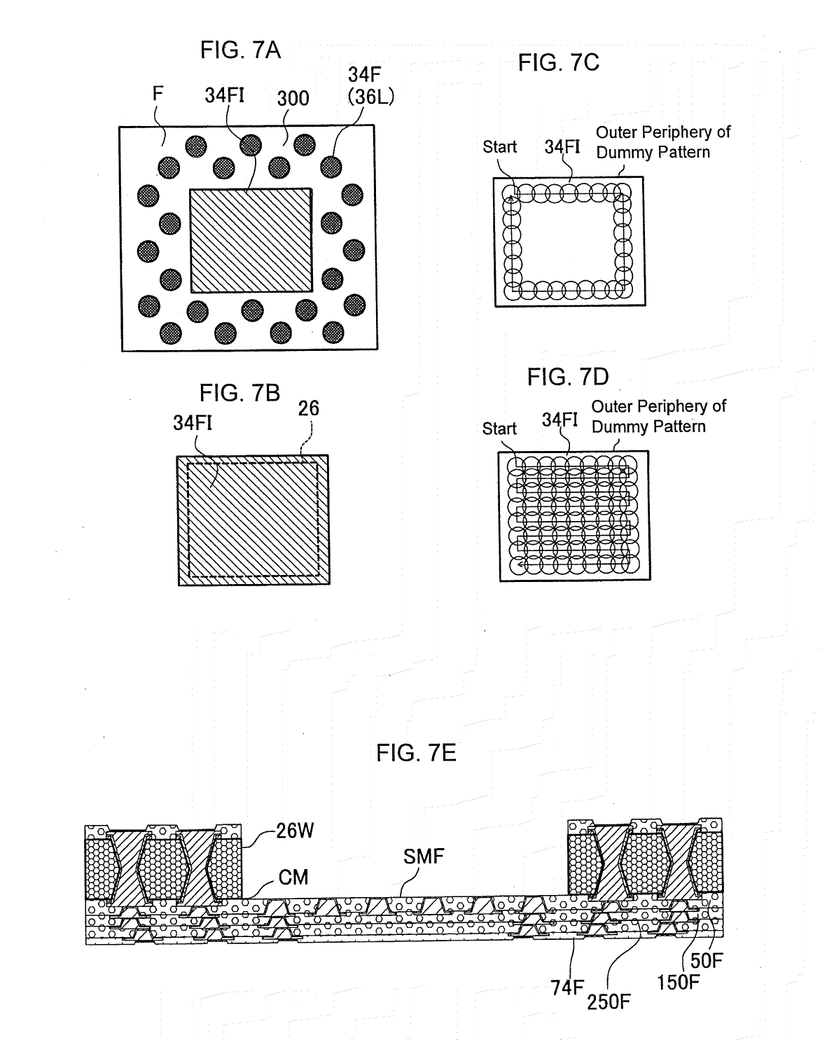

FIG. 7A illustrates a plan view of the intermediate substrate 300. FIG. 7A is a plan view obtained by observing the intermediate substrate from the second conductor layer side. FIG. 7A illustrates the second conductor layer and the second surface (F) of the insulating substrate (20z) that is exposed from the second conductor layer. The dummy pattern (34F1) is formed substantially at a center of the second surface of the insulating substrate. Oblique lines are drawn in the dummy pattern (34F1). The dummy pattern (34F1) covers a predetermined region of the second surface of the insulating substrate (20z). The dummy pattern (34F1) is a so-called solid pattern. The lands (36L) of the through-hole conductors 36 are illustrated around the dummy pattern. Crossing oblique lines are drawn in the lands (36L). FIG. 7B illustrates a positional relation between the opening 26 and the dummy pattern (34FI) and sizes of the two. An outer periphery of the dummy pattern (34FI) is indicated using a solid line; and an outer periphery of the opening 26 is indicated using a dotted line. The dotted line indicates the outer periphery of the opening 26 that is formed on the dummy pattern. As illustrated in FIG. 7B, the dummy pattern (34FI) is larger than the opening 26. Further, the outer periphery of the dummy pattern (34FI) is positioned outside the outer periphery of the opening 26.

The upper side resin insulating layer (50S) is formed on the first surface (S) of the intermediate substrate 300 by hot pressing. The resin insulating layer (first resin insulating layer) (50F) is formed on the second surface (F) of the intermediate substrate, and a second intermediate body 400 is completed (FIG. 3D). The upper side resin insulating layer (50S) and the first resin insulating layer (50F) are of thermosetting type. The resin insulating layers (50F, 50S) contain a resin such as an epoxy resin, and inorganic particles such as silica particles. The resin insulating layers (50F, 50S) are adjusted to have a thermal expansion coefficient of 25-40 ppm. The resin insulating layer (50F) and the resin insulating layer (50S) may further contain a reinforcing member such as a glass cloth. It is desirable that the resin insulating layer (50F) and the resin insulating layer (50S) have the same composition.

The second intermediate body 400 is affixed to both sides of a support film 80 (FIG. 3E). A material of the support film 80 is not particularly limited. For example, a PET material or the like can be used.

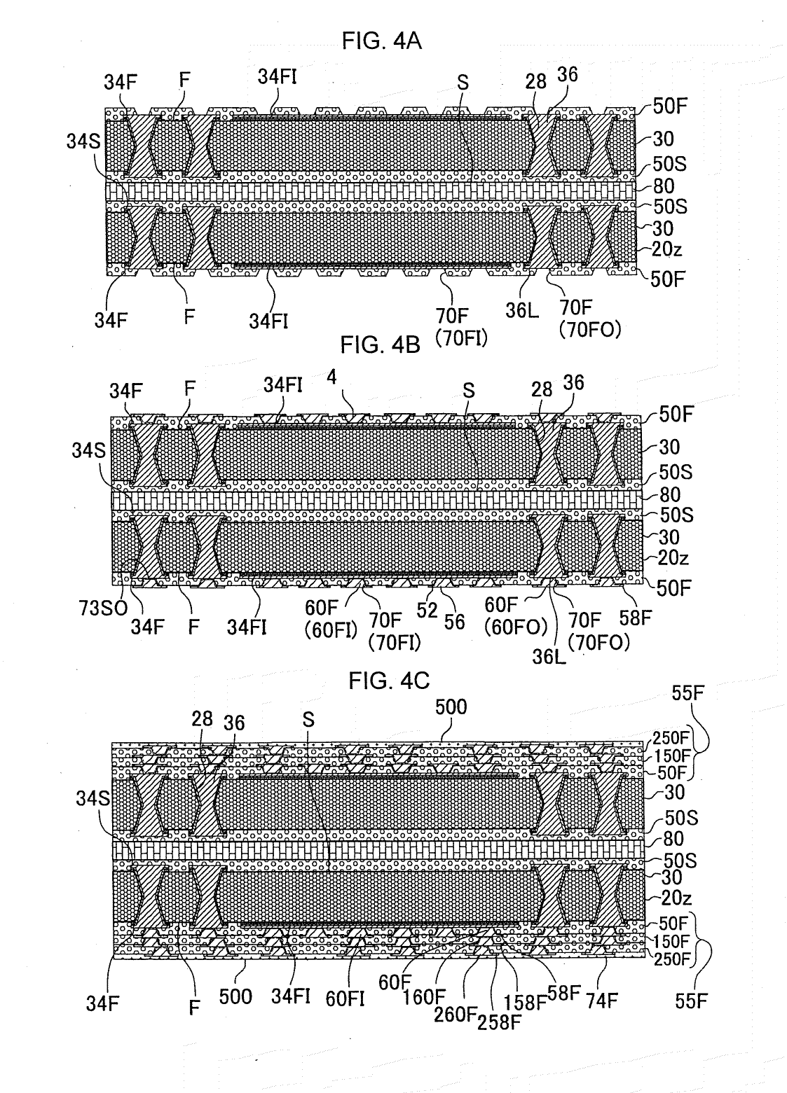

Next, the openings (70F) (70FI, 70FO) for the via conductors that reach the second conductor layer (34F) are formed in the first resin insulating layer (50F) (FIG. 4A). The openings (70F) for the via conductors include the openings (70FI) that reach the dummy pattern (34FI) and the openings (70FO) that reach the second conductor layer other than the dummy pattern. The openings (70FI) are the openings for forming the mounting via conductors. The openings (70FO) are the openings for forming the connection via conductors. The openings (70FO), for example, reach the lands (36L) of the through-hole conductors. A land of a through-hole conductor is formed by a conductor that is formed directly on the through-hole conductor and a conductor that is formed around the through-hole conductor. The conductor layer (58F) is formed on the first resin insulating layer (50F) using a semi-additive method. At the same time, the via conductors (60F) are formed in the openings (70F) (FIG. 4B). The via conductors (connection via conductors) (60FO) that connect to the through-hole conductors are formed in the openings (70FO). The via conductors (mounting via conductors) (60FI) that form the C4 pads are formed in the openings (70FI). The via conductors (60F) have the bottoms. The bottoms of the connection via conductors are in contact with the lands (36L) of the through-hole conductors.

The bottoms of the mounting via conductors are formed on the dummy pattern (34FI). The bottoms of the mounting via conductors are in contact with the dummy pattern.

A metal film can be formed on each of portions of the dummy pattern that are exposed from the openings (70FI). The metal films function as the C4 pads. The metal films are formed of a metal other than copper, and prevent oxidation of the C4 pads (first pads). Examples of the metal of the metal films include gold, palladium, and tin. Nickel can be formed between a metal film and a C4 pad.

The second resin insulating layer (150F) is formed on the first resin insulating layer (50F) and the conductor layer (58F) by hot pressing. The openings (170F) for the second via conductors are formed in the second resin insulating layer (150F). The second resin insulating layer (150F) is of a thermosetting type.

The conductor layer (158F) is formed on the second resin insulating layer (150F). At the same time, the second via conductors (160F) are formed in the openings for the second via conductors. The conductor layer (158F) and the via conductors (160F) are formed using a semi-additive method.

The third resin insulating layer (250F), the conductor layer (258F) and the third via conductors (260F) are formed using the same method as described in the previous paragraph.

The third resin insulating layer (250F) is of a thermosetting type. The resin insulating layers (50F, 150F, 250F) included in the second circuit substrate are of thermosetting type.

The resin insulating layer (74F) on the build-up layer is formed on the third resin insulating layer (250F) and the conductor layer (258F) (FIG. 4C). The resin insulating layer (74F) on the build-up layer is of a thermosetting type.

The upper side resin insulating layer (50S) is of a thermosetting type of the same material as the first resin insulating layer (50F), the second resin insulating layer (150F) and the third resin insulating layer (250F) of the build-up layer and the resin insulating layer (74F) on the build-up layer. The resin insulating layer (74F) on the build-up layer may be a solder resist layer. In this case, the openings are formed by exposure and development processing.

The laminated bodies on both sides of the support film 80 are peeled off from the support film 80, and each become a third intermediate body 500 (FIG. 5A).

FIGS. 7C and 7D are plan views, in which the second surface of the insulating substrate is projected at the same magnification on the dummy pattern.

FIG. 7D illustrates an example of a method for forming the opening 26. Laser is irradiated to the second surface of the insulating substrate via the upper side resin insulating layer. Initially, laser is irradiated to a start position in FIG. 7D. Laser penetrates the insulating substrate and reaches the dummy pattern. Thereafter, the laser irradiation position is sequentially moved along an arrow illustrated in FIG. 7D such that adjacent through holes overlap each other. The insulating substrate on the dummy pattern is removed. The opening 26 that exposes the dummy pattern is formed (FIG. 5B). In the method of FIG. 7D, the opening 26 is formed by through holes. By increasing overlapping portions, the outer periphery of the opening 26 is substantially straight. The dummy pattern that is exposed from the opening 26 is removed by etching. The bottoms of the via conductors (60FI) that form the C4 pads are exposed by the opening 26 (FIG. 5C).

In the present embodiment, the size of the dummy pattern is larger than the side of the opening 26. The dummy pattern between the first circuit substrate and the second circuit substrate is removed. Therefore, as illustrated in FIG. 5C, the mounting area is recessed from the second surface of the first circuit substrate. Further, a space (recess) (55Ff) is formed between the first circuit substrate and the second circuit substrate.

FIG. 7C illustrates another example of the method for forming the opening. In FIG. 7C, a frame-shaped opening that reaches the dummy pattern is formed using laser. An etching solution is introduced into the frame-shaped opening. The dummy pattern is dissolved. In this case, the dummy pattern sandwiched by the insulating substrate and the second circuit substrate is dissolved. As a result, the insulating substrate on a inner side of the opening is peeled off from the second circuit substrate. The insulating substrate on the inner side of the opening can be removed from the second circuit substrate. The opening 26 that exposes the bottoms of the via conductors (60FI) that form the C4 pads is formed (FIG. 5C).

The opening 26 may also be formed using a router.

In the case where the opening 26 is formed using the method illustrated in FIG. 7D, the dummy pattern that is formed of copper is removed by etching. For example, when the bottoms of the mounting via conductors are each formed of a metal film of gold, palladium, tin, and the like, when the dummy pattern is removed by etching, dissolution of the bottoms of the mounting via conductors is suppressed.

The openings (51S) that expose the pads (53S) are formed in the upper side resin insulating layer (50S) using laser.

The openings (71F) that expose the pads (73F) are formed in the resin insulating layer (74F) on the build-up layer on the lower side using laser. The resin insulating layer (74F) on the build-up layer may be a solder resist layer. In this case, the openings (71F) that expose the pads (73F) are formed by exposure processing and development processing.

The pads (73F, 53S) and the protective film 72 on each of the C4 pads (73SI) are formed (FIG. 5D). The protective film is a film for preventing oxidation of the pad. The protective film is formed, for example, by a Ni/Au, Ni/Pd/Au, Pd/Au or OSP (Organic Solderability Preservative) film. The protective film on each of the C4 pads is not depicted in the drawings.

The solder bumps (76F, 76SI, 76SO) can be formed on the pads (73F, 73SI, 53S).

The resin insulating layers (50F, 150F, 250F) each have an upper surface and a lower surface that is on an opposite side of the upper surface. The upper surface of each of the resin insulating layers is a surface close to the first circuit substrate 30; and the lower surface of each of the resin insulating layers is a surface close to the resin insulating layer (74F) on the build-up layer on the lower side. The openings (70F, 170F, 270F) for the via conductors that are respectively formed in the resin insulating layers each taper from the lower surface toward the upper surface. The side walls of the via conductors (60F, 160F, 260F) that are respectively formed in the openings for the via conductors also each taper from the lower surface toward the upper surface.

The conductor layers (58F, 158F, 258F) and the via conductors (60F, 160F, 260F) are each formed by an electroless copper plating film 52 and an electrolytic copper plating film 56 on the electroless copper plating film (see FIG. 4B).

The IC chip 90 is mounted on the printed wiring board via the solder bumps (76SI) on the C4 pads (73SI). The first package substrate (first application example) is completed (FIG. 2A). The IC chip is accommodated in the opening. The IC chip does not extend to the outside of the opening 26. The second package substrate 130 is mounted on the first package substrate 120 via the solder bumps (76SO) (FIG. 2B). The POP substrate (second application example) 2000 is completed.

The mounting via conductors that are each formed by a seed layer 52 and an electrolytic plating 56 are formed on the dummy pattern that is exposed from the openings (70FI). A metal film can be formed between the dummy pattern and the seed layer. By removing only the dummy pattern, the bottoms of the mounting via conductors (60FI) are exposed. The bottoms of the mounting via conductors that are each formed by the seed layer and the third surface of the first resin insulating layer (50F) are positioned on the same plane. The bottoms of the mounting via conductors that are each formed by the metal film and the third surface of the first resin insulating layer (50F) are positioned on the same plane.

### First Modified Example of Embodiment

FIG. 6A illustrates a first modified example of the present embodiment. In the printed wiring board of the first modified example, the opening 26 tapers from first surface (S) toward the second surface (F). The side wall (26W) of the first circuit substrate that is exposed from the opening 26 tapers from the first surface (S) toward the second surface (F). In contrast, the openings for the via conductors that are formed in the second circuit substrate each taper from the fourth surface (W) side toward the third surface (V) side. The openings for the via conductors that are respectively formed in the resin insulating layers each taper from the lower surface toward the upper surface. The openings that are formed in the second circuit substrate and the opening that is formed in the first circuit substrate taper in opposite directions. Since the openings in the second circuit substrate and the opening in the first circuit substrate are oppositely oriented, warpages are offset. Warpage of the printed wiring board that is formed by the first circuit substrate and the second circuit substrate is reduced.

### Second Modified Example of Embodiment

FIG. 7E illustrates a second modified example of the present embodiment.

In FIG. 5B, when the outer periphery of the dummy pattern and the outer periphery of the opening 26 coincide with each other, the second modified example of the printed wiring board that does not have the recess (55Ff) is obtained. In the printed wiring board of the second modified example, the contact point (CM) and the side wall (26W) of the first circuit substrate are positioned substantially on a straight line. The contact point (CM) between the first circuit substrate 30 and the second circuit substrate (55F), and the first circuit substrate and the second circuit substrate near the contact point (CM), are illustrated in FIG. 6C.

The insulating substrate (20z) of the first circuit substrate 30 has a reinforcing member. Therefore, the first circuit substrate has a high strength and a high rigidity. Warpage of the printed wiring board according to the second modified example of the present embodiment is small. According to the second modified example of the present embodiment, warpage due to heat cycles is small. Therefore, s stress acting on the contact point (CM) between the corner part (26E) of the first circuit substrate and the second circuit substrate is small. A crack starting from the contact point is unlikely to occur in the second circuit substrate. The contact point (CM) and the corner part (26E) are illustrated in FIG. 6C.

When a substrate with a built-in electronic component is formed by a coreless substrate and a resin layer that has the accommodating part for accommodating a semiconductor chip, the substrate with a built-in electronic component is likely to have a low strength and a low rigidity. When temperature becomes high due to reflow or the like, such a substrate with a built-in electronic component is likely to have a large warpage. It is likely to become difficult to mount an electronic component to the substrate with a built-in electronic component. Further, connection reliability between the substrate with a built-in electronic component and the electronic component is likely to deteriorate due to heat cycles.

A printed wiring board according to an embodiment of the present invention has a cavity for accommodating an electronic component, reduces warpage and provides high reliability.

A printed wiring board according to an embodiment of the present invention includes: a substrate that has a first surface and a second surface that is on an opposite side of the first surface; a first conductor layer that is formed on the first surface of the substrate; a second conductor layer that is formed on the second surface of the substrate; a through-hole conductor that penetrates the substrate and connects the first conductor layer and the second conductor layer; a build-up layer that is formed on the second surface side of the substrate by alternately laminating conductor layers and insulating layers; a first insulating layer that is formed on the first surface side of the substrate; and a cavity that penetrates the first insulating layer and the substrate to expose the build-up layer that is laminated on the second surface of the substrate. A difference between a thermal expansion coefficient of the substrate and a thermal expansion coefficient of the insulating layers of the build-up layer is 15 ppm or less.

A printed wiring board according to an embodiment of the present invention has an asymmetric structure in which the resin insulating layer is formed on the first surface side of the substrate, and the build-up layer that includes the resin insulating layers is formed on the second surface side of the substrate. Further, the cavity is formed in the substrate and thus rigidity of the substrate is reduced. Therefore, when a thermal stress is applied to the substrate and the insulating layers, warpage is likely to occur. Therefore, the difference between the thermal expansion coefficient of the substrate and the thermal expansion coefficient of the insulating layers of the build-up layer is set to 15 ppm or less, the thermal expansion coefficient of the substrate and the thermal expansion coefficient of the insulating layers of the build-up layer are similar to each other. Thereby, occurrence of warpage is suppressed. Further, since warpage is suppressed, a decrease in connection reliability between an electronic component and the printed wiring board is reduced.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a substrate;
a first conductor layer formed on a first surface of the substrate;
a second conductor layer formed on a second surface of the substrate;
a through-hole conductor penetrating through the substrate such that the through-hole conductor is connecting the first conductor layer and the second conductor layer;
a build-up layer formed on the second surface of the substrate and comprising a plurality of conductor layers and a plurality of insulating layers; and
a first insulating layer formed on the first surface of the substrate such that the first insulating layer is covering the first conductor layer on the first surface of the substrate,
wherein the substrate has a cavity penetrating through the first insulating layer and the substrate such that the cavity is exposing the build-up layer laminated on the second surface of the substrate, and the substrate and the insulating layers in the build-up layer are formed such that a difference between a thermal expansion coefficient of the substrate and a thermal expansion coefficient of the insulating layers in the build-up layer is set in a range of 15 ppm or less.

2. A printed wiring board according to claim 1, wherein the substrate is formed such that the thermal expansion coefficient of the substrate is set in a range of 10 ppm to 25 ppm, and the insulating layers in the build-up layer are formed such that the thermal expansion coefficient of the insulating layers in the build-up layer is set in a range of 25 ppm or 40 ppm.

3. A printed wiring board according to claim 1, wherein the substrate comprises a prepreg material which includes a core material.

4. A printed wiring board according to claim 1, wherein the substrate has a thickness in a range of 50 μm to 200 μm.

5. A printed wiring board according to claim 1, wherein the plurality of insulating layers in the build-up layer does not include core material and includes inorganic filler in an amount of 40 wt % to 80 wt %.

6. A printed wiring board according to claim 1, wherein the through-hole conductor is formed such that the through-hole conductor comprises a taper portion tapering from the first surface toward the second surface of the substrate and a taper portion tapering from the second surface toward the first surface of the substrate.

7. A printed wiring board according to claim 1, wherein the build-up layer comprises a stack via conductor structure comprising a plurality of via conductors.

8. A printed wiring board according to claim 1, wherein the substrate has the cavity formed such that the cavity is tapering from the first surface toward the second surface of the substrate.

9. A printed wiring board according to claim 2, wherein the substrate comprises a prepreg material which includes a core material.

10. A printed wiring board according to claim 2, wherein the substrate has a thickness in a range of 50 μm to 200 μm.

11. A printed wiring board according to claim 2, wherein the plurality of insulating layers in the build-up layer does not include core material and includes inorganic filler in an amount of 40 wt % to 80 wt %.

12. A printed wiring board according to claim 2, wherein the through-hole conductor is formed such that the through-hole conductor comprises a taper portion tapering from the first surface toward the second surface of the substrate and a taper portion tapering from the second surface toward the first surface of the substrate.

13. A printed wiring board according to claim 2, wherein the build-up layer comprises a stack via conductor structure comprising a plurality of via conductors.

14. A printed wiring board according to claim 2, wherein the substrate has the cavity formed such that the cavity is tapering from the first surface toward the second surface of the substrate.

15. A printed wiring board according to claim 3, wherein the substrate has a thickness in a range of 50 μm to 200 μm.

16. A printed wiring board according to claim 3, wherein the plurality of insulating layers in the build-up layer does not include core material and includes inorganic filler in an amount of 40 wt % to 80 wt %.

17. A printed wiring board according to claim 3, wherein the through-hole conductor is formed such that the through-hole conductor comprises a taper portion tapering from the first surface toward the second surface of the substrate and a taper portion tapering from the second surface toward the first surface of the substrate.

18. A printed wiring board according to claim 3, wherein the build-up layer comprises a stack via conductor structure comprising a plurality of via conductors.

19. A printed wiring board according to claim 3, wherein the substrate has the cavity formed such that the cavity is tapering from the first surface toward the second surface of the substrate.

20. A printed wiring board according to claim 4, wherein the plurality of insulating layers in the build-up layer does not include core material and includes inorganic filler in an amount of 40 wt % to 80 wt %.
